(19) United States
(12) Patent Application Publication
(10) Pub. No.: US 2007/0126619 A1
(43) Pub. Date: Jun. 7, 2007

(54) Integrated CMOS temperature sensor and analog to digital converter

(75) Inventor: Don McGrath, Fort Collins, CO (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/292,624

(22) Filed: Dec. 2, 2005

(51) Int. Cl. H03M 1/12

(52) U.S. Cl. 341/155

(57) ABSTRACT

A device and method for efficiently monitoring temperature and providing analog to digital conversion is described. In one embodiment, a single cell temperatures sensor and analog to digital converter, operable in two modes, is provided. The temperature sensor and analog to digital converter may share common components in order to further reduce the amount of substrate area required by the device.

### BACKGROUND

A. Technical Field

The present invention relates generally to the field of integrated circuit design, and more particularly, to the design of temperature sensors and analog to digital converters.

B. Background of the Invention

The importance of integrated circuit design, and its application to numerous different markets, is well known. One important aspect of integrated design is the size, or surface area, required to implement a particular integrated component or components. As large numbers of chips are manufactured, a small reduction in integrated component size may significantly improve manufacturing costs and other factors related to the chips.

Integrated circuits, and component cells therein, often require monitoring various parameters in the circuit in order to evaluate performance and ensure that the circuit is operating within a preferred range of conditions. One such parameter that may be monitored within an integrated circuit is temperature at one or more locations on the chip. Personal computers, signal processors, and high-speed graphics adapters are few of the various devices that benefit from such temperature monitoring. Oftentimes, a temperature sensor may use a relationship between the amount of current through a particular components and a corresponding temperature value. For example, current may be used to sense die temperature during product reliability testing, enclosure qualification or other event by associating a current level through the substrate with a temperature level.

Another component that may be integrated within a chip is an analog to digital converter (“ADC”). Analog signals can be converted to digital signals using various methods such as successive approximation, delta modulation, pulse code modulation (“PCM”), sigma modulation, etc. The actual implemented analog to digital conversion method may depend on a number of factors including the application requirements of the system, the performance requirements, and cost. An ADC may be used within a circuit for applications such as battery voltage, supply voltage or other DC quantity.

An ADC using sigma-delta modulation often provides high resolution and low distortion in the conversion process. An exemplary sigma-delta modulator is shown in FIG. 1. A basic first order sigma-delta modulator consists of an integrator and a comparator, with a 1bit digital to analog converter (“DAC”) in a feedback loop. Referring to FIG. 1, an input signal is fed into the modulator via a summing junction 102. An output from the summing junction 102 is connected to an input of an integrator 104, which outputs an integrated signal value corresponding to the integrator 104 input. The integrator 104 output signal is compared with a reference value at a comparator 106, which acts as a one-bit quantaizer. The comparator 106 generates a one bit output (“high” or “low”) depending on whether the integrator output is positive or negative. The comparator output is fed back to the input summing junction 102 via a one-bit DAC 108, to be compared with the input signal at the summing junction 102.

Temperature sensor and converter components are typically integrated using two distinct cells within a circuit design and operate independently of each other. As shown in FIG. 2, a temperature sensor 202 and an analog to digital converter 204 are shown as two different cells operating independent of each other. The temperature sensor 202 senses one or more temperatures within a circuit or on a silicon substrate and provides a digital temperature value at output 202a. The analog to digital converter 204 converts for an analog input 204a into a corresponding digital output 204b. The temperature sensor 202 and the analog to digital converter 204 are independent cells and occupy different spaces on a semiconductor substrate. Furthermore, there is not any integration in which component size or component surface area is reduced by allowing the temperature sensor 202 and analog to digital converter 204 to share sub-components.

Accordingly, there is a current need for a single cell temperature sensor and analog to digital converter.

### SUMMARY OF THE INVENTION

A system, apparatus and method are described that provide a single cell, dual-mode integrated device that monitors temperature in a substrate, integrated circuit, or component therein, and provides conversion of an analog signal to a digital signal. In one embodiment of the present invention a temperature sensor mode is provided to output the temperature in digital form. Another mode is provided for sampling and converting an analog signal into an equivalent digital signal.

In one of the embodiments of the present invention, a temperature sensor mode is provided that monitors the current from either or both of PMOS and NMOS current sources and a temperature is estimated relative to this measured current. A sigma-delta modulator may be used having feedback to control the current flowing through PMOS current source and the NMOS current source. In this particular embodiment, the stream of binary digits from the sigma delta modulator is processed at a digital decimation filter to remove various noises present in the data. The output from the digital decimation filter corresponds to digital value of the temperature.

In another embodiment of the present invention, an analog to digital converter mode is provided to enable conversion of one or more analog signals to a corresponding digital signal(s). The analog signal is sampled using an input sampling capacitor and fed to an input of the integrator. A comparator, coupled to the integrator, produces a stream of binary digits in response to the comparison of the integrator output to the comparison value generated by a reference sampling capacitor. A feedback DAC is used to control the coupling of the reference sampling capacitor between at least two voltage references. The comparator output may be processed to remove noise from the oversampled signal. The digital equivalent of the analog signal is made available after processing it at the digital decimation filter.

Various embodiments of the invention may provide a means for integrating a temperature sensor and an analog to digital converter on a single IC or cell.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. 1 illustrates one embodiment of the sigma delta modulator, which may be used for analog to digital conversion.

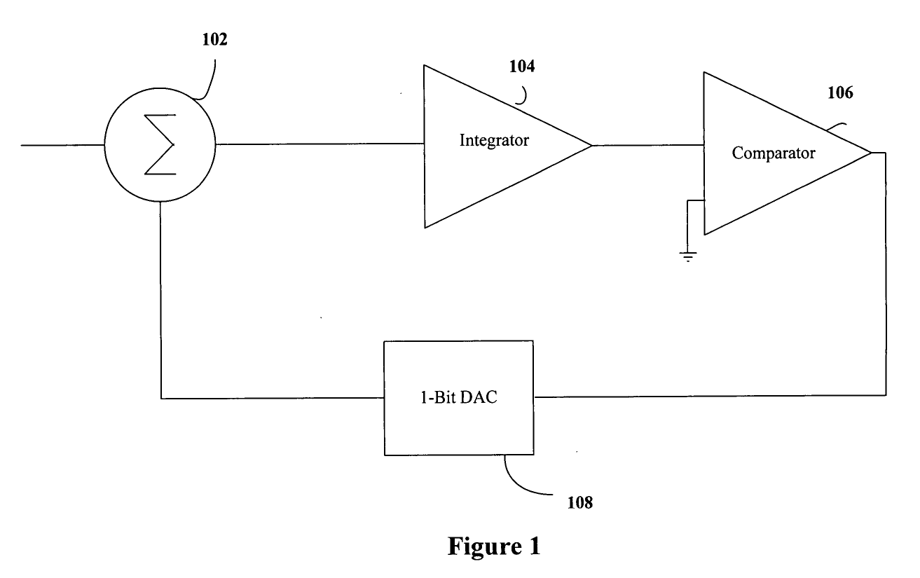

FIG. 2 illustrates a system comprising an analog to digital converter and temperature sensor, in accordance with prior art.

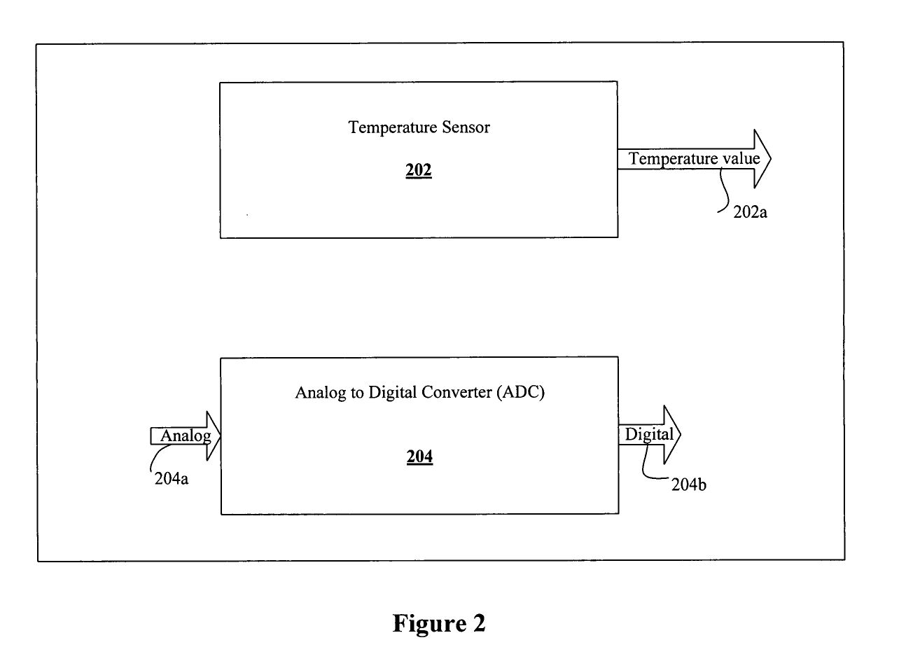

FIG. 3 illustrates a single cell temperature sensor and analog to digital converter according to one embodiment of the invention.

FIG. 4 illustrates a detailed block diagram of a single cell temperature sensor and analog to digital converter according to one embodiment of the invention.

### DETAILED DESCRIPTION OF THE PREFERRED EMBODIMENTS

A system, apparatus and method for providing temperature sensing and analog to digital conversion in a single cell that may be integrated into a system are described. In one embodiment of the invention, the cell may operate in one of two modes of operation. A first mode is provided that senses temperature by measuring current at a location(s) on a chip and provides a digital output related to the temperature. A second mode is provided that converts an analog signal to a digital signal using an oversampling method.

In the following description, for purpose of explanation, specific details are set forth in order to provide an understanding of the invention. It will be apparent, however, to one skilled in the art that the invention may be practiced without these details. One skilled in the art will recognize that embodiments of the present invention, some of which are described below, may be incorporated into a number of different integrated circuits, chips, packages, etc. The embodiments of the present invention may be present in hardware or firmware. Structures and devices shown below in block diagram are illustrative of exemplary embodiments of the invention and are meant to avoid obscuring the invention. Furthermore, connections between components within the figures are not intended to be limited to direct connections. Rather, data between these components may be modified, re-formatted or otherwise changed by intermediary components.

Reference in the specification to “one embodiment” or “an embodiment” means that a particular feature, structure, characteristic, or function described in connection with the embodiment is included in at least one embodiment of the invention. The appearances of the phrase “in one embodiment” in various places in the specification are not necessarily all referring to the same embodiment.

a) Overview

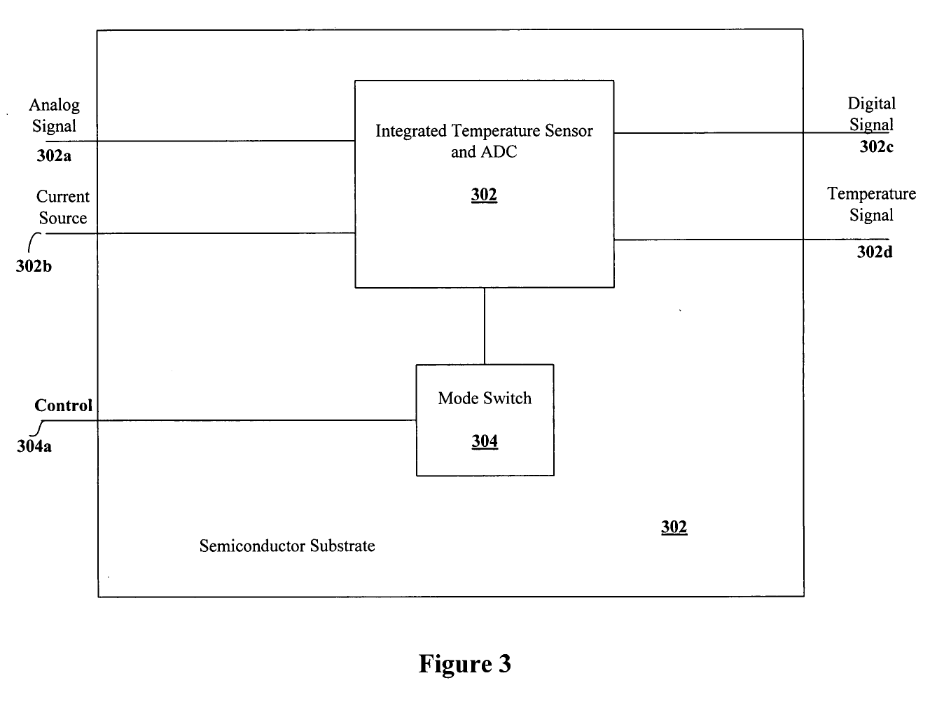

A dual mode, single cell temperature sensor and ADC device 300 is illustrated in FIG. 3 according to one embodiment of the invention. The device 300 comprises an integrated temperature sensor and ADC 302 connected to a mode switch 304 that controls which mode the device 300 operates. A control input 304a is coupled to the mode switch 304 and controls the mode switch 304 operations. One skilled in the art will recognize that the mode switch 304 may be provided by various structures and designs including a plurality of switches that effectively turn certain components within the device 300 on or off.

While working in a temperature sensor mode, the temperature sensor and ADC device 300 is designed to accept input from current source 302b. The input signal from current source 302b is processed and a temperature value or values is generated using a relationship between a current level and a temperature value. A temperature signal 302d is generated which may contain a digital signal representing the sensed temperature within a circuit or substrate.

Using the control input 304a the mode switch 304 can be directed to signal the integrated temperature sensor and ADC device 302 to operate in an ADC mode. While working in the ADC mode, the device 300 receives an analog signal 302a, samples the analog signal and generates a digital signal 302c. In one embodiment of the invention, the digital signal 302c is a digital equivalent of the signal fed at input analog signal 302a in which a sigma-delta modulator is used.

The temperature sensor and ADC device 302 is contained within a single cell which may be integrated on a substrate and also shares certain components that provides further area efficiencies when integrated on the substrate. One skilled in the art will recognize that various features and structural designs may be used to create this single cell device, of which one embodiment is described below.

b) Temperature Sensor

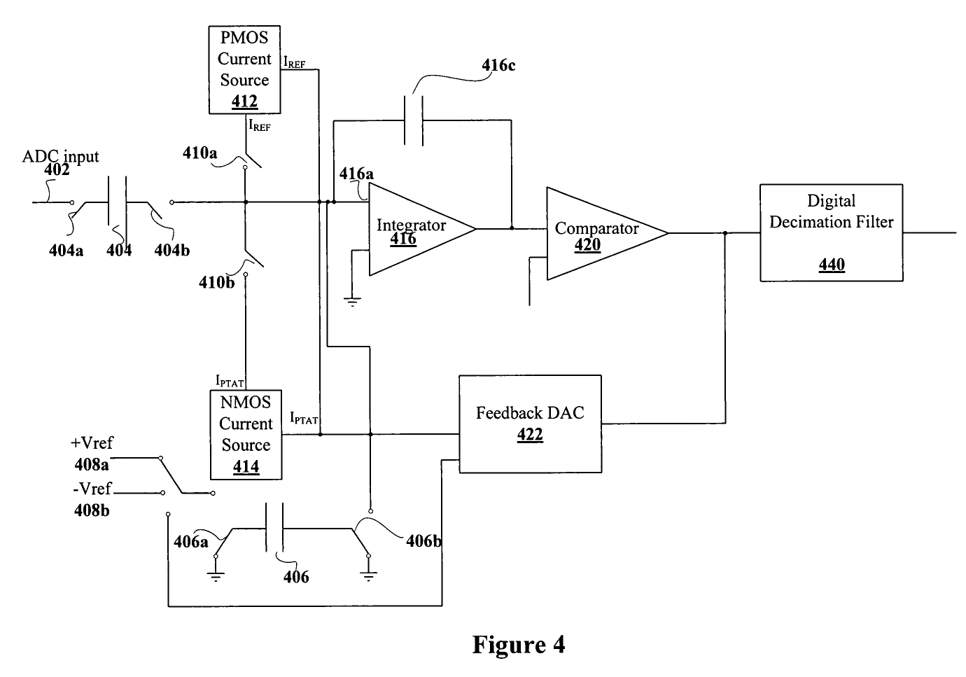

A detailed illustration of both temperature sensor and ADC functionality and structure are shown in FIG. 4 according to one embodiment of the invention. One skilled in the art will recognize that other types and structures of temperature sensors and ADCs may be combined in a single cell and share common components; all of which are intended to fall within the scope of the present invention.

In this particular embodiment, a PMOS current source 412 and NMOS current source 414 are used to produce current corresponding to a substrate temperature value. Generally known circuit techniques are known in which a current is nearly independent of temperature (I_{REF}) and a current that is proportional to temperature (I_{PTAT}) may be created. In one embodiment of the invention, the PMOS current source 412 generates a first current independent of temperature and the NMOS current source 414 generate a second current that is proportional to the substrate temperature.

The current from the PMOS current source 412 and NMOS current source 414 are fed to a summing node 416a of an integrator 416 by switches 410a, 410b that effectively couple the current sources to the temperature sensor. The PMOS current source 412 and NMOS current source 414 are balanced to keep a static set point; thereby, pumping zero current into the inverting node 416a of the integrator. As the temperature being sensed goes lower than the static set point, the net current flows from the NMOS current source 414. If the temperature goes higher than the static set point, the net current will flow from PMOS current source 412.

The output of the integrator 416 changes relative to the current from the PMOS current source 412 and NMOS current source 414. An integrator feedback capacitor 416c is used to store a charge for the integrator function. The output of the integrator 416 is provided to a comparator 420 which compares this output to a threshold comparison value of the comparator 420. The comparator 420 outputs a low or zero, if the input to the comparator is below the comparison point. Conversely, the comparator 420 outputs a high or one, if the input to the comparator is higher than the comparison point.

The output from the comparator 420 is fed to a feedback digital to analog converter (“DAC”) 422, which may comprise a set of switches used to produce an analog equivalent of the digital signal produced by the comparator 420. The analog output at the DAC 422 is further used to control the PMOS current source 412 and NMOS current source 414 to draw currents so as to neutralize the net current flowing into the integrator 416.

The sequence of outputs from the comparator 420, in form of a data stream, is also provided to a digital decimation filter 440. The purpose of the digital decimation filter 440 is to extract information from this data stream and reduce the data rate to a more useful value. In one embodiment of the invention, the digital decimation filter 440 averages the 1bit data stream, improves the resolution, and removes quantization noise that is outside the band of interest. The digital decimation filter 440 may also determine the signal bandwidth, settling time, and stopband rejection.

c) Analog to Digital Converter

Referring once again to FIG. 4, a detailed illustration of an analog to digital converter is shown according to one embodiment of the invention. An analog signal is provided at an ADC input 402. An input sampling capacitor 404 is charged by connecting it to the ADC using a switch 404a, while keeping the switch 404b grounded. The sampled charge at input sampling capacitor 404 is then transferred to the inverting input of the integrator 416 via switch 404b. The output of the integrator 416 is compared with the comparison point of the comparator 420 and generates a sampled digital equivalent of the analog signal at the ADC input 402.

The comparator 420 produces a series of binary output in terms of “0” and/or “1” in response to the comparison. If the comparator output is “1” then the feedback DAC 422 signals the switch 406a to connect to −Vref 408b. This action of the feedback DAC 422 neutralizes the net current flowing into the integrator 416. Similarly, if the output of the comparator 420 is “0” then the feedback DAC 422 signals switch 406a to connect to +Vref 408a.

The switch 406b is connected to ground while a reference capacitor 406 is charged by +Vref 408a or −Vref 408b. The charge deposited on the reference capacitor 406 is transferred to the inverting input of the integrator 416a and switch 406a is grounded while the switch 406b is transferring the charge to the inverting input of the integrator 416.

The series of “1” and/or “0” produced at comparator 420 is passed through the digital decimation filter 440 to produce the digital output corresponding to the analog signal. Since the comparator 420 output represents an oversampled signal, the digital decimation filter 440 is used to process the information from this data stream. In particular, the digital decimation filter 440 averages the 1bit data stream, improves the resolution, and removes quantization noise that is outside the band of interest. The digital decimation filter 440 may also determine the signal bandwidth, settling time, and stopband rejection.

The present invention may be implemented using various embodiments of the sigma delta modulator circuit wherein the initial signal is processed to produce digital signal and the feedback effectively provides for current neutralization as required for the device operation. One skilled in the art will recognize that the temperature sensor and the ADC may share various different components in order to reduce the amount of substrate area required to implement the device.

Although the embodiments above have been described in considerable detail, other versions are possible. Numerous variations and modifications will become apparent to those skilled in the art once the above disclosure is fully appreciated. It is intended that the following claims be interpreted to embrace all such variations and modifications.

I claim:

1. A temperature sensor and analog to digital converter device comprising:
a temperature sensor having an input that senses a current level and an output that generates a digital representation of a temperature;
an analog to digital converter having an input that receives an analog signal and an output that generates a sampled digital signal;
a mode switch, coupled to a control input, that selects a temperature sensor mode or an analog to digital conversion mode for the device; and
wherein the temperature sensor and the analog to digital converter share at least one common component.

2. The device of claim 1 wherein the temperature sensor and the analog to digital converter share an integrator.

3. The device of claim 1 wherein the temperature sensor and the analog to digital converter share a comparator.

4. The device of claim 1 further comprising a digital decimation filter, coupled to the outputs of the temperature sensor and the analog to digital converter, that further processes a digital signal from one of the outputs.

5. The device of claim 1 wherein the analog to digital converter comprises a sigma-delta modulator.

6. The device of claim 1 wherein the temperature sensor senses a current level at a PMOS current source and an NMOS current source.

7. The device of claim 6 wherein the current from the PMOS current source and the NMOS current source changes relative to feedback from a comparator within the temperature sensor.

8. The device of claim 7 wherein the PMOS current source and NMOS current source are isolated during the operation of the analog to digital converter.

9. The device of claim 1 wherein the analog to digital converter comprises a sampling capacitor and a reference capacitor that control an output on an integrator and a digital output on a comparator.

10. The device of claim 9 wherein the sampling capacitor and the reference capacitor are isolated during the operation of the temperature sensor.

11. A method for proving a temperature sensor and an analog to digital converter within an integrated cell, the method comprising:
selecting a first operational mode, from a plurality of operational modes, in which temperature sensing is performed by the integrated cell;
selecting a second operational mode, from a plurality of operational modes, in which analog to digital conversion is performed by the integrated cell; and
wherein the temperature sensing and the analog to digital conversion processes share at least one component within the integrated cell.

12. The method of claim 11 wherein the at least on component comprises a comparator.

13. The method of claim 11 wherein the temperature sensing includes detecting a current level at a PMOS current source and an NMOS current source and providing a temperature value relative to the sensed current levels.

14. The method of claim 13 wherein a digital decimation filter is provided to further process the temperature value.

15. The method of claim 11 wherein the analog to digital conversion includes producing an oversampled digital signal using a sampling capacitor and a reference capacitor to control an output of a comparator.

16. The method of claim 15 wherein a digital decimation filter is provided to further process the oversampled digital signal.

17. A temperature sensor and analog to digital converter device comprising:
a temperature sensor comprising:
a plurality of current sources from which a temperature level may be estimated from a current level;
an integrator, having an inverting input coupled to the plurality of current sources and a feedback integrating capacitor, that generates an output relative to a current level on at least one current source within the plurality of current sources; and
a comparator, coupled to the integrator, that compares an output of the integrator to a reference value to generate a digital value representative of the temperature level;
an analog to digital converter comprising:
a sampling capacitor that samples an incoming analog signal;
the integrator, coupled to receive the sampled analog signal and generate a digital signal;
the comparator, coupled to receive the digital signal from the integrator and provide a digital signal representative of the incoming analog signal; and
a reference capacitor coupled to control a voltage level on the inverting input of the integrator;
and wherein the temperature sensor and the analog to digital converter are integrated within the same cell.

18. The device of claim 17 further comprising:
a feedback digital to analog converter, coupled to the output of the comparator and the plurality of current sources, that controls the current levels on the plurality of current sources relative to the output of the comparator.

19. The device of claim 17 further comprising:
a feedback digital to analog converter, coupled to the output of the comparator and the reference capacitor, that controls a voltage level on the integrator.

20. The device of claim 17 further comprising a plurality of switches within the device to switch between a temperature sensing mode and an analog to digital conversion mode.
